(19) United States
(12) Patent Application Publication
(10) Pub. No.: US 2025/0141409 A1
(43) Pub. Date: May 1, 2025

(54) A CONFIGURABLE DOHERTY POWER AMPLIFIER ARRANGEMENT

(71) Applicant: Telefonaktiebolaget LM Ericsson (publ), Stockholm (SE)

(72) Inventors: Mingquan BAO, Västra Frölunda (SE); David GUSTAFSSON, Sävedalen (SE)

(73) Assignee: Telefonaktiebolaget LM Ericsson (publ), Stockholm (SE)

(21) Appl. No.: 18/837,138

(22) PCT Filed: Feb. 11, 2022
(86) PCT No.: PCT/SE2022/050150

§ 371 Date: Aug. 8, 2024

(51) Int. Cl. H03F 1/56; H03F 1/02; H03F 3/21; H03F 3/213

(52) U.S. Cl. CPC H03F 1/56; H03F 1/0288; H03F 3/211; H03F 3/213; H03F 2200/222; H03F 2200/336; H03F 2200/387

(57) ABSTRACT

A power amplifier arrangement (100) comprises comprising a first power amplifier (P1) and a second power amplifier (P2) of a Doherty power amplifier (110). The power amplifier arrangement (100) further comprises an input power splitter (PS), a quadrature coupler (120) comprising two coupled transmission lines (TL1/TL2) and an output impedance matching network (IMN). A current of the second power amplifier (P2) and an input impedance (RL) of the output impedance matching network (IMN) are tunable such that an efficiency of the power amplifier arrangement (100) is configurable for different output power back-off levels by changing the current of the second power amplifier (P2. Da) and the input impedance (RL) of the output impedance matching network (IMN).

### TECHNICAL FIELD

Embodiments herein relate to power amplifier arrangement. In particular, they relate to configurable Doherty power amplifier arrangement. Further, the embodiments relate to an electronic device comprising the power amplifier arrangement.

### BACKGROUND

In a wireless communication system, a transmitter employs power amplifiers (PA) to increase radio frequency (RF) signal power before transmission. A PA is expected to amplify input signals linearly and generate output signals with larger power but with identical characteristics to the input signals.

New frequency bands are assigned for the 5th and 6th generation (5G/6G) wireless communication networks, along with increased signal bandwidth. To get high spectral efficiency and high-speed data transmission, highly modulated signals have been applied in the 5G/6G wireless communication networks, which have a large peak-to-average power ratio (PAPR). Meanwhile, the 3G, 4G, 5G and 6G communication standards are different, their modulation formats are different too. Different modulated signals have different PAPRs.

Therefore, a desired power amplifier should have a wide bandwidth, a high power added efficiency (PAE) over a large power back-off range from the maximum output power and a reconfigurable power back-off range to adapt to different PAPRs. PAE is defined by an equation PAE=100×(Pout-Pin)/PDC, where PDC is input direct current (DC) power, Pout is RF output power and Pin is RF input power of the PA. A power back-off level in a PA is a power level below a saturation point at which the PA will continue to operate in the linear region even if there is a slight increase in the input power level. Usually, a PA operates close to the saturation point as that is where efficiency is maximum. The amount by which the power level is lowered is called power back-off. There are two power back-off types, input power back-off (IPBO) and output power back-off (OPBO). The IPBO is the power level at a PA input relative to the input power which produces the maximum output power. The OPBO is the power level at a PA output relative to the maximum output power level possible. For example, if the maximum output power level is +40 dBm, the measured output power level of the amplifier is +34 dBm, then the OPBO is 6 dB.

For enhancing PA's efficiency at power back-off, a Doherty power amplifier (DPA) is the most widely applied topology. The DPA consists of a main amplifier and an auxiliary amplifier, as well as an impedance inverter. It has been investigated extensively how to extend DPA's bandwidth. Various techniques have been proposed.

In US 2004/0189380 A1, it is proposed to use quadrature coupler in a DPA to improve the DPA's efficiency at power back-off. In R. Giofrè et al. “New output combiner for Doherty amplifiers”, IEEE MICROWAVE AND WIRELESS COMPONENTS LETTERS, VOL. 23, NO. 1, pp. 31-33, January 2013, it is discussed how a quadrature coupler can be used to extend the bandwidth of the DPA.

In G. Reza Nikandish et. al., “Unbalanced Power Amplifier: An Architecture for Broadband Back-Off Efficiency Enhancement”, IEEE JOURNAL OF SOLID-STATE CIRCUITS, VOL. 56, NO. 2, pp. 367-381, February 2021, a coupled line based quadrature coupler is used in a DPA. The coupled line quadrature coupler has the best bandwidth performance among quadrature couplers.

In A. M. Mahmoud et. al., “Reconfigurable Doherty Amplifier for Efficient Amplification of Signals with Variable PAPR”, IEEE MTT-S International Microwave Symposium Digest (IMS), 2013, a reconfigurable DPA to adapt different PAPR is realized by varying the gate bias of the auxiliary amplifier, i.e., the output current of the auxiliary amplifier, and meanwhile, the input and output matching networks of the main and auxiliary are tuned too.

A modified DPA was proposed in D. Gustafsson, et. al., “A Novel Wideband and Reconfigurable High Average Efficiency Power Amplifier”, 2012 IEEE MTT-S Int. Microwave Symp. Dig., June 2012. By tuning the DC supply voltage of the main amplifier, the peak of the PAE at power back-off is reconfigurable from less than 6 dB up to 10 dB of OPBO.

However, there are problems with the existing solutions. For examples, DPAs based on transmission lines (TLs) have a limited bandwidth, even though multi-TLs inverter increases the bandwidth with a certain extension. DPAs based on quadrature couplers have better bandwidth performance than TLs based ones. However, the peak drain efficiency (PDE) is at 6 dB of OPBO. Drain efficiency (n) is the ratio of output RF power (Pout) to the input DC power (PDC) defined as Drain Efficiency (n)=Pout/PDC. It is not shown if DPAs based on quadrature couplers are applicable for deep OPBO, i.e. larger than 6 dB of OPBO.

The quadrature coupler based DPA disclosed in US 2004/0189380 is asymmetric, the size of the auxiliary amplifier is larger than that of the main amplifier. It needs a gate control circuit probably to improve the efficiency at deep back-off level. Adding the gate control circuit increases complicity of the DPA.

The unbalanced power amplifier disclosed by G. Reza Nikandish et. al., where the isolation port of the coupler is connected to a resistor which dissipates RF power. It therefore reduces the drain efficiency at OPBO, or at peak power, or both.

The modified DPA proposed by D. Gustafsson, et. al. requires a reduced voltage supply of the main amplifier. The reduced voltage supply of the main amplifier results in a reduced maximum power of the main amplifier P_{max,main}, which in turn gives low power utilization factor, defined as P_{max,DPA}/(P_{max,main}+P_{max,aux}), where P_{max,DPA} is the power of the DPA, P_{max,aux.} is the power of the auxiliary amplifier.

### SUMMARY

Therefore, it is an object of embodiments herein to provide a power amplifier arrangement with improved performance and efficiency at different power back-off levels.

According to one aspect of embodiments herein, the object is achieved by a power amplifier arrangement. The power amplifier arrangement comprises a Doherty power amplifier comprising a first power amplifier having an input and an output, which is a main amplifier in the Doherty power amplifier, and a second power amplifier having an input and an output, which is an auxiliary amplifier in the Doherty power amplifier.

The power amplifier arrangement further comprises an input power splitter having an input and a first output and a second output.

The power amplifier arrangement further comprises a quadrature coupler having an input port, a through port, a coupled port and an isolated port. The quadrature coupler comprises two coupled transmission lines. A first terminal of the first transmission line is the input port, a second terminal of the first transmission line is the through port. A first terminal of the second transmission line is the coupled port and a second terminal of the second transmission line is the isolated port.

The power amplifier arrangement further comprises an output impedance matching network having an input and an output.

The input of the first power amplifier is coupled to the first output of the input power splitter. The output of the first power amplifier is coupled to the coupled port of the quadrature coupler. The input of the second power amplifier is coupled to the second output of the input power splitter. The output of the second power amplifier is coupled to the through port of the quadrature coupler. The input port of the quadrature coupler is coupled to the input of the output impedance matching network. The output of the impedance matching network is coupled to a load. The isolated port of the quadrature coupler is coupled to an Alternating Current (AC) ground.

A current of the second power amplifier and an input impedance of the output impedance matching network are tunable such that an efficiency of the power amplifier arrangement is configurable for different output power back-off levels by changing the current of the second power amplifier and the input impedance of the output impedance matching network.

According to some embodiments herein, the characteristic impedance of the coupled transmission lines may be determined based on a desired load resistance of the first power amplifier and a coupling coefficient of the two coupled transmission lines, wherein at the desired load resistance, the first power amplifier delivers a maximum output power.

According to some embodiments herein, the input impedance of the output impedance matching network may be determined based on a desired load resistance of the first power amplifier, a coupling coefficient of the two coupled transmission lines and an output power back-off level.

According to embodiments herein, a quadrature coupler based DPA is proposed, which can be designed to have efficiency peak at deep OPBO level, i.e. the OPBO level is larger than 6 dB. The quadrature coupler is realized by two coupled transmission lines with a length of a quarter wavelength at a centre frequency of an RF signal. The coupled transmission lines are designed based on the desired load resistance of the main power amplifier and the coupling coefficient of the two coupled transmission lines. The coupling coefficient is less than one. The larger is the coupling coefficient, the wider is the bandwidth of the quadrature coupler based DPA. The efficiency of the quadrature coupler based DPA at power back-off is reconfigurable by changing the current of the auxiliary amplifier, as well as the input impedance of the output impedance matching network.

The power amplifier arrangement according to embodiments herein has some advantages, such as having efficiency peak at deep output power back-off level, i.e. OPBO>6 dB; having wide bandwidth; reconfigurable efficiency at power back-off, etc. The power amplifier arrangement according to embodiments herein is able to adapt to varies PAPRs of different modulated RF signals.

Therefore, embodiments herein provide a power amplifier arrangement with improved performance and efficiency at different power back-off levels.

### BRIEF DESCRIPTION OF THE DRAWINGS

Examples of embodiments herein are described in more detail with reference to attached drawings in which:

FIG. 1 is a schematic block diagram illustrating a power amplifier arrangement according to embodiments herein;

FIG. 2 is a simplified schematic block diagram illustrating the power amplifier arrangement according to embodiments herein;

FIG. 3 is a diagram showing simulation results on drain efficiency versus output power for different output power back-off levels for the power amplifier arrangement according to embodiments herein;

FIG. 4 is a schematic block diagram illustrating an example of configurable power amplifier arrangement according to embodiments herein;

FIG. 5 is a schematic block diagram illustrating another example of configurable power amplifier arrangement according to embodiments herein;

FIG. 6 is a diagram showing simulation results on drain efficiency versus output power at different normalized frequencies for the power amplifier arrangement according to embodiments herein;

FIG. 7 is a diagram showing simulation results on drain efficiency versus normalized frequencies for the power amplifier arrangement according to embodiments herein and a conventional DPA;

FIG. 8 is a diagram showing simulation results on normalized small signal gain versus normalized frequencies for the power amplifier arrangement according to embodiments herein and a conventional DPA;

FIG. 9 is a diagram showing simulation results on drain efficiency versus normalized frequencies for different coupling coefficients of the quadrature coupler for the power amplifier arrangement according to embodiments herein; and

FIG. 10 is a block diagram illustrating an electronic device/apparatus in which embodiments herein may be implemented.

### DETAILED DESCRIPTION

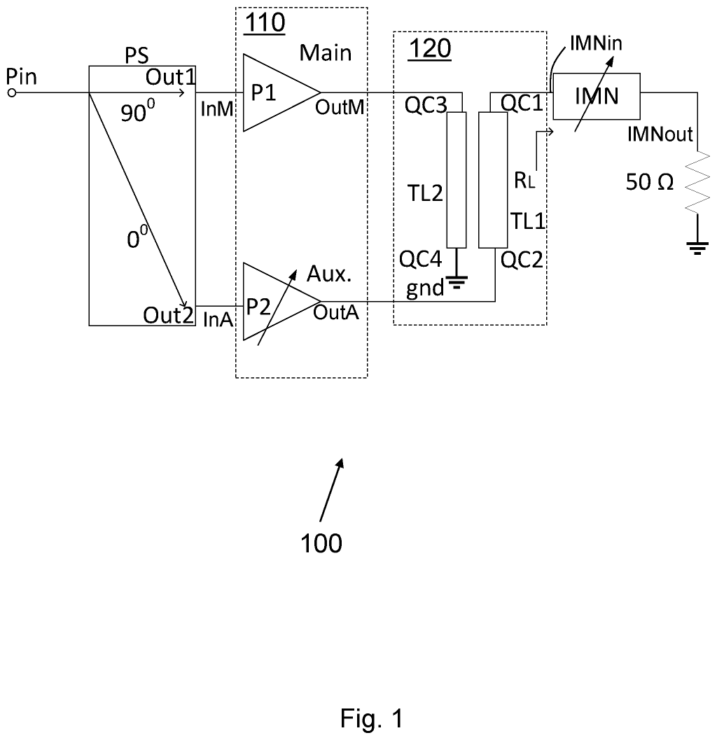

FIG. 1 shows a schematic block diagram of a power amplifier arrangement 100 according to embodiments herein, which is a variant of a Doherty power amplifier based on quadrature coupler. The power amplifier arrangement 100 comprises a first power amplifier P1 having an input InM and an output OutM, which is a main amplifier Main in the Doherty power amplifier 110, and a second power amplifier P2 having an input InA and an output OutA, which is an auxiliary amplifier Aux. in the Doherty power amplifier 110.

The power amplifier arrangement 100 further comprises an input power splitter PS having an input port Pin and two output ports, a first output Out1 and a second output Out2.

The power amplifier arrangement 100 further comprises a quadrature coupler 120 having an input port QC1, a through port QC2, a coupled port QC3 and an isolated port QC4. The quadrature coupler 120 comprises two coupled transmission lines TL1, TL2. A first terminal of the first transmission line TL1 is the input port QC1 and a second terminal of the first transmission line TL1 is the through port QC2. A first terminal of the second transmission line TL2 is the coupled port QC3 and a second terminal of the second transmission line TL2 is the isolated port QC4.

The power amplifier arrangement 100 further comprises an output impedance matching network IMN having an input IMNin and an output IMNout.

The input InM of the first power amplifier P1 is coupled to the first output Out1 of the input power splitter PS.

The output OutM of the first power amplifier P1 is coupled to the coupled port QC3 of the quadrature coupler 120.

The input InA of the second power amplifier P2 is coupled to the second output Out2 of the input power splitter PS.

The output OutA of the second power amplifier P2 is coupled to the through port QC2 of the quadrature coupler 120.

The input port QC1 of the quadrature coupler 120 is coupled to the input IMNin of the output impedance matching network IMN.

The output IMNout of the impedance matching network IMN is coupled to a load, e.g. 50Ω.

The isolated port QC4 of the quadrature coupler 120 is coupled to an Alternating Current (AC) ground gnd.

A current of the second power amplifier P2 and an input impedance of R_{L} the output impedance matching network IMN are tunable such that an efficiency of the power amplifier arrangement 100 is configurable for different output power back-off levels by changing the current of the second power amplifier P2 and the input impedance R_{L} of the output impedance matching network IMN.

The power amplifier arrangement 100 is a Doherty PA based on a quadrature coupler with two coupled transmission lines, which can have DE peak at deep OPBO level, i.e. OPBO>6 dB. The isolation port QC4 of the quadrature coupler 120 is grounded. The main and the auxiliary amplifiers P1, P2 are connected to the output ports of the power splitter PS having a 90-degree phase difference. The impedance matching network IMN transfers the impedance R_{L} to 50Ω.

According to embodiments herein, the characteristic impedance Z₀ of the two coupled transmission lines TL1 and TL2 may be determined based on a desired load resistance R_{opt,m} of the first power amplifier P1 and a coupling coefficient k of the two coupled transmission lines TL1/TL2. At the desired load resistance R_{opt,m}, the first power amplifier P1 delivers a maximum output power.

According to embodiments herein, the input impedance R_{L} of the output impedance matching network IMN may be determined based on the desired load resistance R_{opt,m} of the first power amplifier P1, the coupling coefficient k of the two coupled transmission lines TL1/TL2 and an output power back-off level, OPBO.

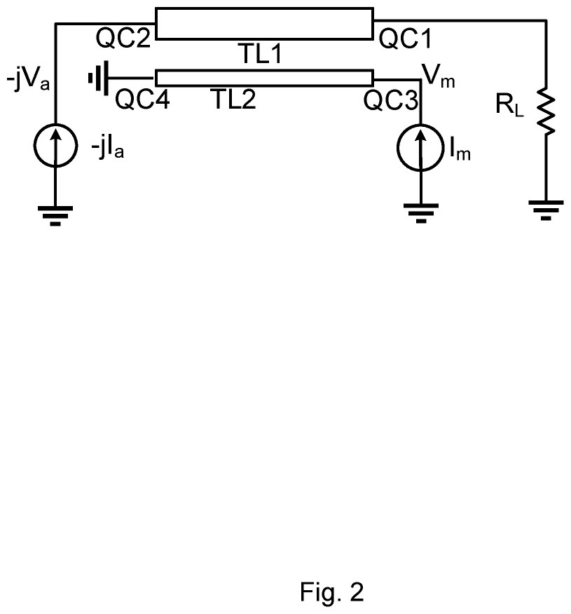

In the flowing, how to design the power amplifier arrangement 100 for any choice of OPBO levels will be described with reference to FIG. 2.

FIG. 2 shows a simplified schematic of the power amplifier arrangement 100, wherein the quadrature coupler 120 comprising two coupled transmission lines TL1 and TL2 is shown, and the main and auxiliary amplifiers P1, P2 are represented by a voltage controlled current source, Im and Ia, respectively. The isolation port QC4 is grounded and the input port QC1 is terminated by a resistor Ry, which represents the input impedance of the impedance matching network IMN.

The length of the two coupled transmission lines TL1, TL2 may be a quarter-wavelength at a centre frequency of an RF signal. At the through port QC2 and coupled port QC3 connected to the outputs of the main and the auxiliary amplifiers P1, P2, the impedance matrix is given by

$$[ \begin{matrix}{V}_{m} \\ - j {V}_{a}\end{matrix} ] = [ \begin{matrix}{Z}_{11} & {Z}_{12} \\ {Z}_{21} & {Z}_{22}\end{matrix} ] [ \begin{matrix}{I}_{m} \\ - {jI}_{a}\end{matrix} ] \qquad ( 1 )$$

Where, Vₘ and Iₘ are the magnitude of the fundamental output voltage and current of the main amplifier P1, Vₐ and Iₐ are the magnitude of the fundamental output voltage and current of the auxiliary amplifier P2. To combine currents from the main and the auxiliary amplifiers P1, P2 constructively, the current from the auxiliary amplifier P2 should 90° ahead the current from the main amplifier P1, thus, Iₐ and Vₐ are multiplied by a negative imaginary number−j in equation (1).

Zᵢⱼ is given by

$${Z}_{11} = {{R}_{L} ( \frac{{Z}_{o e} + {Z}_{o o}}{{Z}_{o e} - {Z}_{o o}} )}^{2} \qquad ( 2 a )$$

$${Z}_{12} = {Z}_{21} = - \frac{2 \cdot {Z}_{o e} \cdot {Z}_{o o}}{{Z}_{o e} - {Z}_{o o}} j \qquad ( 2 b )$$

$${Z}_{22} = 0 \qquad ( 2 c )$$

Where, Zₒₑ and Zₒₒ represent the characteristic impedance of even and odd modes of the coupled transmission lines TL1/TL2, respectively. They are related to the characteristic impedance Z₀ of the coupled transmission lines TL1/TL2, Z₀=\sqrt{ZₒₑZₒₒ}, and coupling coefficient k of the coupled transmission lines TL1/TL2, 0<k<1, by equations:

$${Z}_{o e} = {Z}_{0} \sqrt{\frac{1 + k}{1 - k}} \qquad ( 3 a )$$

$${Z}_{o o} = {Z}_{0} \sqrt{\frac{1 - k}{1 + k}} \qquad ( 3 b )$$

Even and odd modes are the two main modes of propagation of a signal through a pair of coupled transmission lines. Odd mode impedance is defined as impedance of a single transmission line when the two coupled transmission lines are driven differentially with signals of the same amplitude and opposite polarity. Even mode impedance is defined as impedance of a single transmission line when the two coupled transmission lines are driven with a common mode signal of the same amplitude and the same polarity.

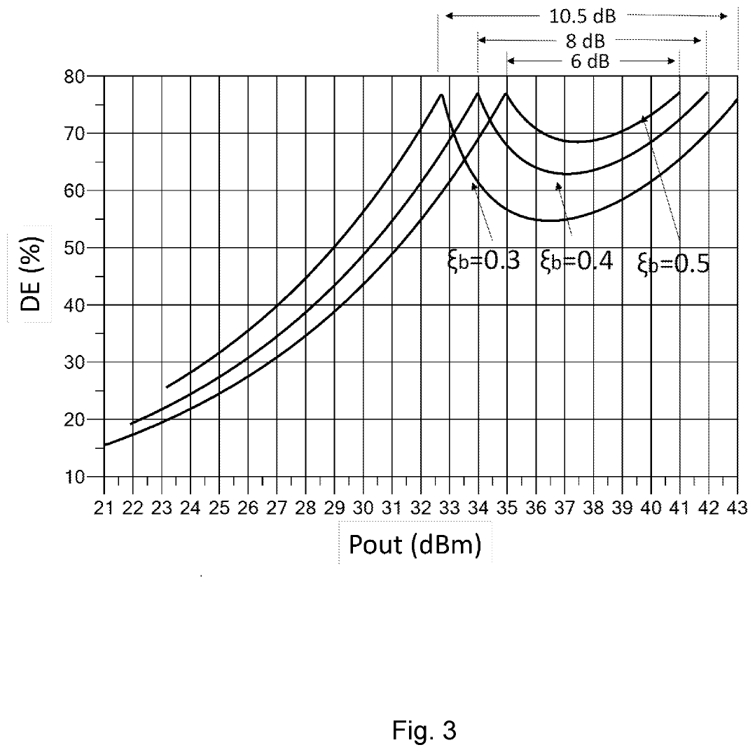

A Doherty PA has two drain efficiency (η) peaks, one peak at the maximum output power, and another one at an output power back-off level, as shown in FIG. 3, where the drain efficiency versus different output power back-off levels OPBO₁=10.5 dB, OPBO₂=8 dB, and OPBO₃=6 dB is shown. The different output power back-off levels are associated with different output voltage levels represented by ξ_{b} which is a ratio of the actual output voltage Vₒᵤₜ to the maximum output voltage V_{out,max}, ξ_{b}=Vₒᵤₜ/V_{out, max}, 0<ξ_{b}<1. For examples, for OPBO₁=10.5 dB, ξ_{b}=0.3, for OPBO₂=8 dB, 5=0.4, and for OPBO₃=6 dB, 5=0.5. That is the output voltage level 5 is related to the output power back-off level P_{BO} by an equation P_{BO}=−20 log (ξ_{b}). As shown in FIG. 3, the efficiency of the power amplifier arrangement 100 is configurable for different output power back-off levels. There are drain efficiency peaks at the power back-off levels of 10.5 dB, 8 dB and 6 dB.

At the output voltage level ξ_{b}, the auxiliary amplifier P2 is at an onset, i.e., the auxiliary amplifier P2 is just about to turn on or is just getting started, the current of the auxiliary amplifier P2 is 0, i.e. Ia=0, and the load impedance of the main amplifier P1 should be

$${Z}_{11} = \frac{{V}_{m}}{{I}_{m}} = \frac{{R}_{opt , m}}{{ξ}_{b}} \qquad ( 4 )$$

At PAE peak of the maximum output power,

$${I}_{a , max} = \frac{1 - {ξ}_{b}}{{ξ}_{b}} \cdot {I}_{m , max} \qquad ( 6 )$$

$${R}_{opt , m} = \frac{{V}_{m , max}}{{I}_{m , max}} \qquad ( 6 )$$

where V_{m,max} and I_{m,max} represent the magnitudes of the maximum fundamental output voltage and current from the main amplifier P1, respectively, and V_{a,max} and I_{a,max} represent the magnitudes of the maximum fundamental output voltage and current from the auxiliary amplifier P2, respectively.

From equations (1), (4)-(6), obtaining

$${Z}_{12} = {Z}_{21} = - j {R}_{opt , m} \qquad ( 7 )$$

From equations (2)-(7), obtaining

$${Z}_{0} = \frac{k}{\sqrt{1 - {k}^{2}}} \cdot {R}_{o p t , m} \qquad ( 8 )$$

$${R}_{L} = \frac{{k}^{2}}{{ξ}_{b}} \cdot {R}_{o p t , m} \qquad ( 9 )$$

When the main amplifier's R_{opt,m} and I_{m,max}, as well as OPBO (ξ_{b}) are determined, the maximum current of the auxiliary amplifier I_{a,max} is determined by equation (5).

The equations above describe how to build a quadrature coupler based DPA which has efficiency peak for any choice of output power back-off OPBO levels. When the main amplifier's R_{opt,m} and I_{m,max}, as well as the output power back-off level OPBO (ξ_{b}) are determined, the maximum current of the auxiliary amplifier I_{a,max} is determined by equation (5). Assuming the maximum current/max is proportional to the size of transistor, the ratio of the size of the auxiliary and the main amplifier transistors can be determined too. The load of the quadrature coupler, i.e., the input impedance R_{L} of the impedance matching network IMN can be calculated according to equation (9), then the impedance matching network IMN is designed, which has the impedance transfer ratio R_{L}/50, assuming a 50Ω interface to an antenna.

For example, consider three quadrature coupler based Doherty power amplifiers (QC DPAs) having the same main amplifier size and current, but different efficiencies at output power back-off level, all having R_{opt,m} equals to 50Ω and I_{m,max} equals to 1 A. The quadrature coupler is the same for all three cases with k=0.85 and Z₀=80.7Ω, while the auxiliary amplifier has different sizes, i.e., different I_{a,max}, depending on OPBO levels, see the parameters in three cases in Table 1.

TABLE 1
Parameters of the QC DPAs

| | | | |
|---|---|---|---|
| OPBO (dB) | 6 | 8 | 10.5 |
| ζ_{b} | 0.5 | 0.4 | 0.3 |
| I_{a, max} (A) | 1 | 1.5 | 2.33 |
| R_{opt, m} (Ω) | 50 | 50 | 50 |
| R_{L} (Ω) | 72.2 | 90.3 | 120.4 |
| Pₘₐₓ (dBm) | 41 | 42 | 43 |

As seen from Table 1, the deeper the OPBO level is, the larger is the maximum current of the auxiliary amplifier, thus, the larger is the maximum output power of the QC DPA. Furthermore, the load of the quadrature coupler R_{L} is varied for different OPBO levels. The deeper the OPBO level is, the larger is R_{L}.

FIG. 3 is a plot showing simulated drain efficiencies (DE) versus output power for the power amplifier arrangement 100, where the current of the auxiliary amplifier P2 and the input impedance R_{L} of the output impedance matching network IMN are configured with the values of three QC DPAs shown in Table 1. The power amplifier arrangement 100 has DE peaks at OPBO levels of 6 dB, 8 dB, as well as 10.5 dB. That is the efficiency of the power amplifier arrangement 100 is configurable for different output power back-off levels and may have different efficiency at the output power back-off region when I_{a,max} and R_{L} are changed simultaneously.

The power amplifier arrangement 100 may be configurable in varies ways with respect to the current of the second power amplifier P2/Da and input impedance R_{L} of the output impedance matching network IMN.

According to some embodiments herein, the output impedance matching network IMN may comprise multiple switchable impedance matching networks and the input impedance of the output impedance matching network IMN is changed by selecting different impedance matching network.

According to some embodiments herein, the second power amplifier P2/Da may comprise a transistor. Gate or base voltage of the second power amplifier P2/Da may be tuned for changing the current of the second power amplifier P2/Da.

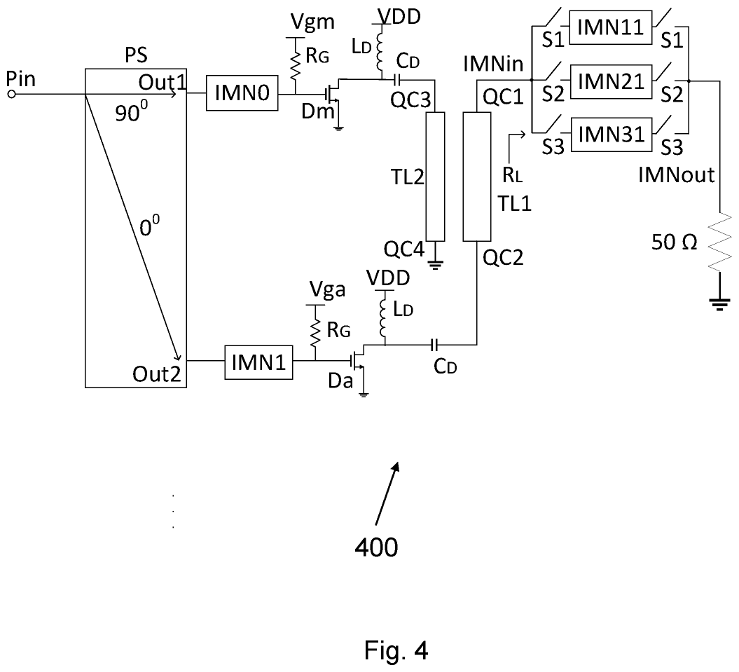

FIG. 4 shows an example of configurable power amplifier arrangement 400 according to embodiments herein. The configurable power amplifier arrangement 400 comprises multiple switchable impedance matching networks IMN11, IMN21, IMN31 and the input impedance Ry of the output impedance matching network IMN may be changed by selecting different impedance matching networks. The power amplifier arrangement 400 has two amplifier devices, a main amplifier device Dm and an auxiliary amplifier device Da, both shown as a field-effect transistor (FET). The device size of the auxiliary amplifier Da should be large enough to deliver I_{a,max} for the PAE peak at the deepest output power back-off level. I_{a,max} is tuned by changing a gate voltage Vga of the auxiliary amplifier device Da, letting the I_{a,max} varying from 1 A to 2.33 A, corresponding to 6 dB to 10.5 dB of OPBO levels. Meanwhile, R_{L} can be changed by selecting different impedance matching networks IMNi1, i=1,2,3, which has different impedance transformation ratios R_{L}/50, assuming the load impudence of the power amplifier arrangement 400 is 50Ω. For instance, when switch S1 is switched on, IMN11 which transfers R_{L}=72.2 Ω into 50Ω is selected. In this case, the DE peak is at 6 dB of OPBO level, see Table 1. When switch S2 is switched on, IMN21 which transfers R_{L}=90.3Ω into 50Ω is selected, and the DE peak moves to 8 dB of OPBO level. When switch S3 is switched on, IMN31 which transfers R_{L}=120.4Ω into 50Ω is chosen, and the DE peak is at 10.5 dB of OPBO level.

In the configurable power amplifier arrangement 400, shunted inductors LD at drains of Dₘ and Dₐ are AC chokes and capacitors C_{D} are AC coupling capacitors to block DC. R_{G} at gates of Dₘ and Dₐ are bias resistors. IMN₀ and IMN₁ are impedance matching networks at the inputs of the main and auxiliary amplifiers respectively.

Therefore, according to some embodiments herein, the input of the first or main power amplifier P1/Dₘ may be coupled to the first output of the input power splitter PS via a first input impedance matching network IMN₀ and the input of the second or auxiliary power amplifier P2/Da may be coupled to the second output of the input power splitter PS via a second input impedance matching network IMN₁.

The topology of the configurable power amplifier arrangement 400 is also applicable to a conventional DPA. Namely the quadrature coupler may be replaced by a quarter-wavelength TL or other kinds of couplers, for instance, branch-line coupler.

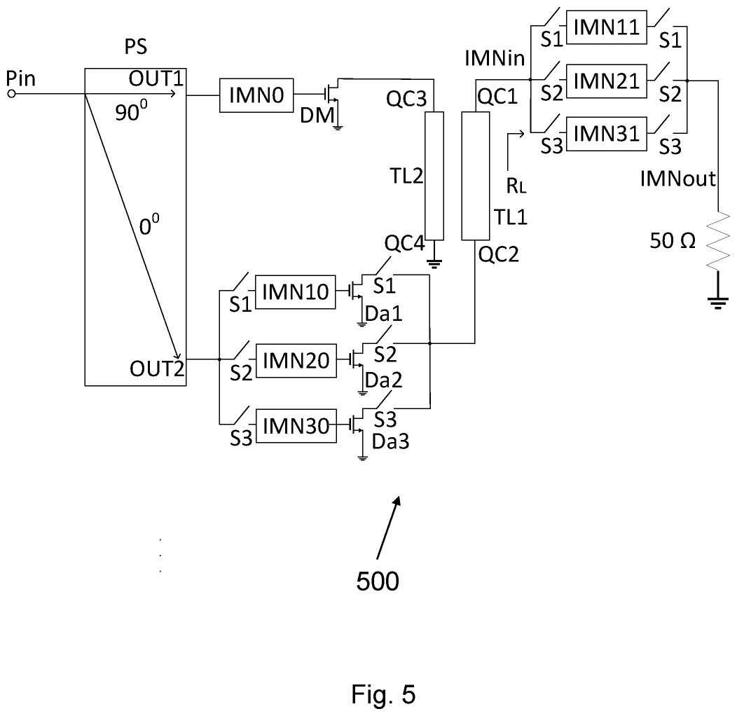

According to some embodiments herein, the second power amplifier P2/Da may comprise multiple transistors with different sizes for changing the current of the second power amplifier P2/Da. FIG. 5 shows another example of configurable power amplifier arrangement 500 according to embodiments herein. The power amplifier arrangement 500 has a main amplifier device Dₘ and a number of auxiliary amplifier devices Da1, Da2, Da3 . . . , all shown as a field-effect transistor (FET). The maximum current of auxiliary amplifier I_{a,max} can be changed by turning “on” or selecting different devices Dai, i=1, 2, 3 which has different sizes. Da2 and Da3 are 1.5 and 2.33 times as large as Da1, respectively. Da1, Da2 and Da3 are able to deliver a maximum current I_{a,max} of 1A, 1,5A and 2, 33 A, respectively. IMNi0, i=1, 2, 3 are impedance matching networks at gates of auxiliary amplifier devices Dai, i=1, 2, 3, respectively.

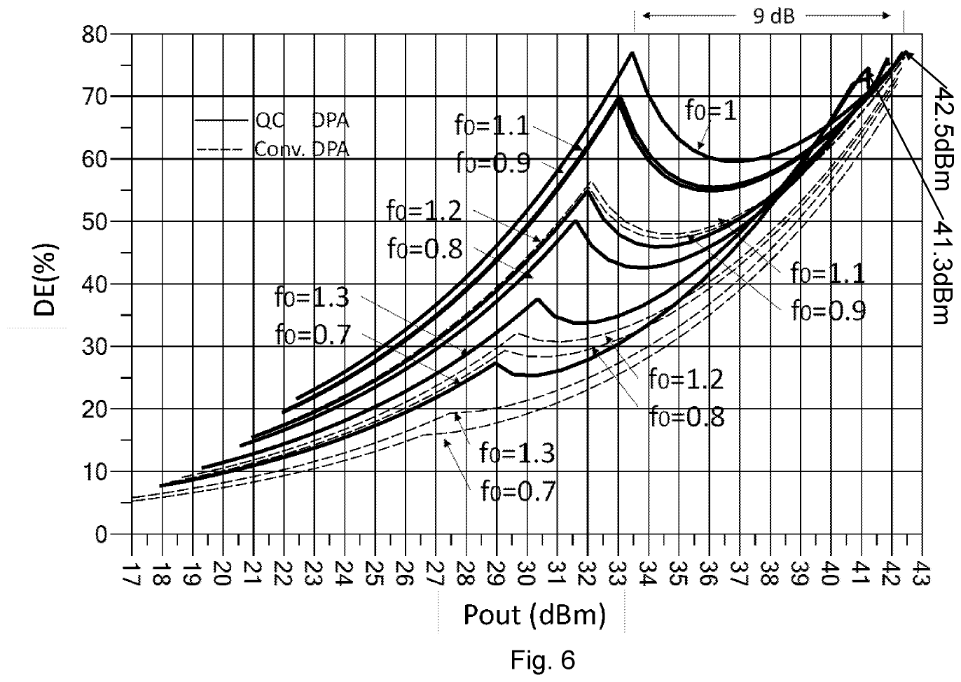

To demonstrate the performance and advantages of the power amplifier arrangement 100, 400, 500 according to embodiments herein, simulations have been performed for a QC DPA designed according to embodiments herein and a conventional DPA. The QC DPA according to embodiments herein has a main amplifier with R_{opt,m} and I_{m,max} equal to 50Ω and 1 A, respectively, and an auxiliary amplifier with a maximum current I_{a,max} of 1.81 A. The quadrature coupler has a coupling coefficient k of 0.8 and characteristic impedance Z₀ of 66.6Ω. R_{L} for the QC DPA is 90.2Ω. R_{L} for the conventional DPA is 17.7Ω. The QC DPA in this example is configured for DE peak at 9 dB output power back-off level, i.e. ξ_{b}=0.355. FIG. 6 shows the simulated drain efficiency versus output power at different normalized frequencies f₀, f₀=f/f_{c}, from 0.7 to 1.3 with a step of 0.1, where the solid lines are the simulated drain efficiency for the QC DPA according to embodiments herein and the dash lines are the simulated drain efficiency for the conventional DPA. The center frequency f_{c} in this example is f_{c}=4 GHz.

As can be seen from FIG. 6, at the centre frequency f_{c} equal to 4 GHz, i.e., the normalized frequency f₀=1, the DE curves of two DPAs are overlapped completely. As the frequency departs from the centre frequency, the efficiency of the QC DPA will decrease.

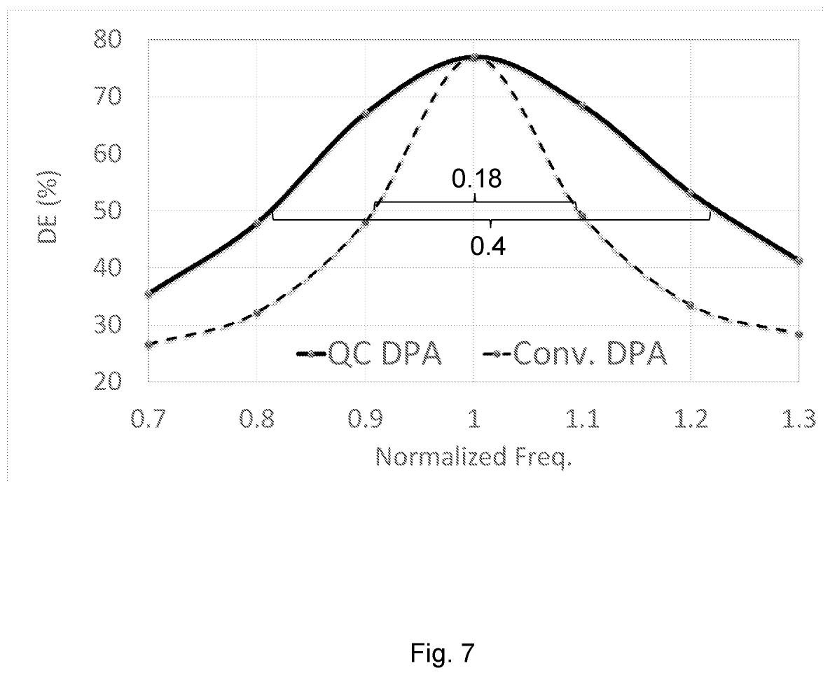

However, as the frequency deviates from the centre frequency, the QC DPA according to embodiments herein has a better DE than the conventional DPA at output power back-off. FIG. 7 shows the simulated DE versus normalized frequency f₀ for the QC DPA according to embodiments herein (solid line) and the conventional DPA (dotted line). The normalized frequency bandwidth for DE larger than 50% is about 0.4 for the QC DPA according to embodiments herein and 0.18 for the conventional DPA.

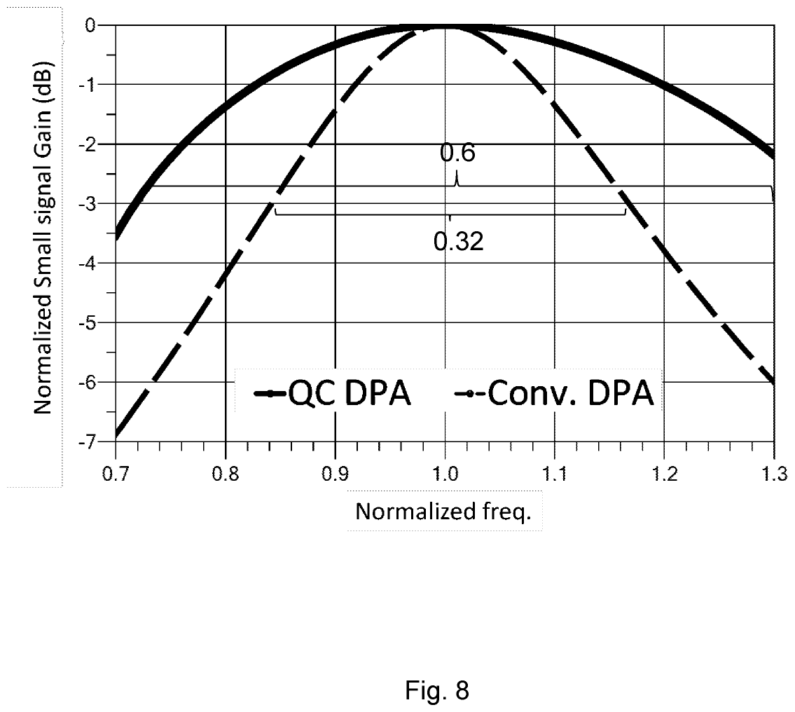

When the normalized frequency f₀ is swept from 0.7 to 1.3, the maximum output powers of the QC DPA and conventional DPA vary about 1 dB, from 41.3 dBm to 42.5 dBm, as shown in FIG. 6. However, the small signal gain varies 7 dB for the conventional DPA and 3.5 dB for the QC DPA, as shown in FIG. 8, where the simulation results on normalized small signal gain versus normalized frequency for the QC DPA and conventional DPA are shown. The normalized 3-dB bandwidths of the QC DPA and the conventional DPA are about 0.6 and 0.32, respectively.

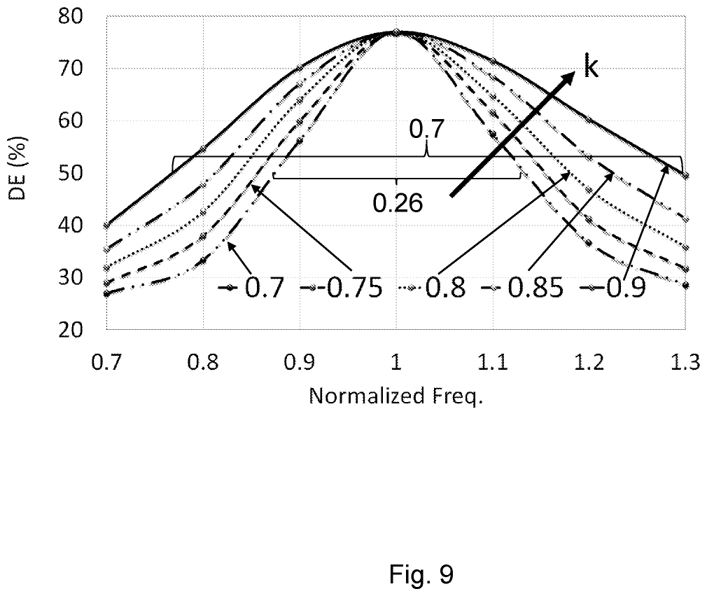

Furthermore, the bandwidth of the QC DPA depends on the quadrature coupler's coupling coefficient k, as shown in FIG. 9, where the simulated results of drain efficiency of the QC DPA versus the normalized frequency at different coupling coefficients are shown. In those simulations, a DE peak is at 9 dB OPBO. However, the impedance Z₀ and R_{L} are varied for different coupling coefficients k according to equations (8), (9). The larger the coupling coefficient k is, the wider is the bandwidth of the QC DPA. For a DE larger than 50%, the normalized bandwidth is 0.26 and 0.7, as k is equal to 0.7 and 0.9, respectively.

Therefore, it has been demonstrated that the power amplifier arrangement 100, 400, 500 according to embodiments herein has advantages of having efficiency peak at deep power back-off levels, e.g. at OPBO levels of 8 dB, 9 dB, 10.5 dB etc., i.e. OPBO>6 dB; having wider bandwidth than the conventional DPA; having reconfigurable efficiency at different output power back-off levels. The power amplifier arrangement 100, 400, 500 according to embodiments can also adapt to the variations of the PAPR of the different modulated RF signals.

To summarize, the power amplifier arrangement 100, 400, 500 according to embodiments herein is a quadrature coupler based DPA, which can be designed to have efficiency peak at deep OPBO levels. The quadrature coupler 120 may be realized by two coupled transmission lines TL1/TL2 with a length of a quarter wavelength at a centre frequency of an RF signal. The coupled transmission lines TL1/TL2 are designed based on the desired load resistance R_{opt,m} of the main power amplifier P1, Dm and the coupling coefficient k of the two coupled transmission lines TL1/TL2. The larger is the coupling coefficient k, the wider is the bandwidth of the quadrature coupler based DPA 100, 400, 500. The efficiency of the quadrature coupler based DPA 100, 400, 500 at an output power back-off level is reconfigurable by changing the current of the auxiliary amplifier P2, Da, as well as the input impedance R_{L} of the output impedance matching network IMN.

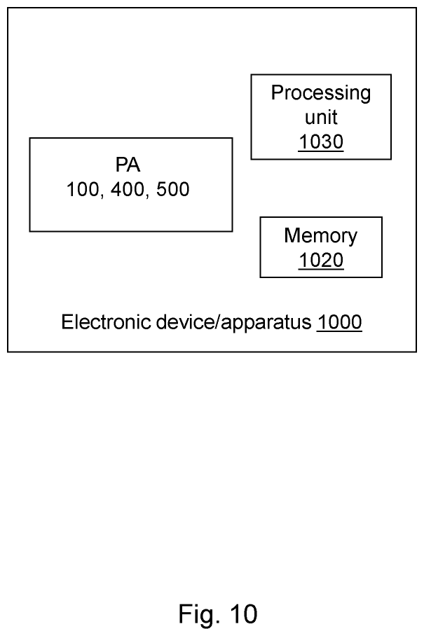

The power amplifier arrangement 100, 400, 500 according to embodiments herein may be employed in various electronic devices or apparatus etc. FIG. 10 shows a block diagram for an electronic device or apparatus 1000. The electronic device or apparatus 1000 comprises a power amplifier arrangement 100, 400, 500 according to embodiments herein. The electronic device 1000 may be a transmitter, a transceiver, a base station, a mobile device, a user equipment, a wireless communication device, a radar for a communication system. The electronic device 1000 may comprise other units, where a memory 1020, a processing unit 1030 are shown.

The embodiments herein are not limited to the above described preferred embodiments. Various alternatives, modifications and equivalents may be used. Those skilled in the art will understand that the power amplifier arrangement 100, 400, 500 according to embodiments herein may be implemented by any semiconductor technology, e.g. Bi-polar, N-type Metal Oxide Semiconductor (NMOS), P-type Metal Oxide Semiconductor (PMOS), Complementary Metal Oxide Semiconductor (CMOS), Silicon on Insulator (SOI) CMOS, field-effect transistor (FET), MOSFET or Micro-Electro-Mechanical 10 Systems (MEMS) technology etc.

When using the word “comprise” or “comprising” it shall be interpreted as non-limiting, i.e. meaning “consist at least of”. Therefore, the above embodiments should not be taken as limiting the scope of the invention, which is defined by the appended claims.

The invention claimed is:

1. A power amplifier arrangement comprises:
a first power amplifier having an input and an output, which is a main amplifier in a Doherty power amplifier, and a second power amplifier having an input and an output, which is an auxiliary amplifier in the Doherty power amplifier;
an input power splitter having an input and a first output and a second output;
a quadrature coupler having an input port, a through port, a coupled port and an isolated port, wherein the quadrature coupler comprises two coupled transmission lines, a first terminal of the first transmission line is the input port, a second terminal of the first transmission line is the through port, a first terminal of the second transmission line is the coupled port and a second terminal of the second transmission line is the isolated port;
an output impedance matching network having an input and an output; and wherein the input of the first power amplifier is coupled to the first output of the input power splitter;
the output of the first power amplifier is coupled to the coupled port of the quadrature coupler;
the input of the second power amplifier is coupled to the second output of the input power splitter;
the output of the second power amplifier is coupled to the through port of the quadrature coupler;
the input port of the quadrature coupler is coupled to the input of the output impedance matching network;
the output the impedance matching network is coupled to a load; and
the isolated port of the quadrature coupler is coupled to an Alternating Current (AC) ground; and wherein a current of the second power amplifier and an input impedance of the output impedance matching network are tunable such that an efficiency of the power amplifier arrangement is configurable for different output power back-off levels by changing the current of the second power amplifier and the input impedance of the output impedance matching network.

2. The power amplifier arrangement according to claim 1, wherein a characteristic impedance of the two coupled transmission lines is determined based on a desired load resistance of the first power amplifier and a coupling coefficient of the two coupled transmission lines, wherein at the desired load resistance, the first power amplifier delivers a maximum output power.

3. The power amplifier arrangement according to claim 2, wherein the characteristic impedance of the two coupled transmission lines is determined by an equation
$${Z}_{0} = \frac{k}{\sqrt{1 - {k}^{2}}} \cdot {R}_{opt , m} ,$$
where Z₀ is the characteristic impedance of the coupled transmission lines, R_{opt,m} is the desired load resistance of the first power amplifier, and k is the coupling coefficient of the two coupled transmission lines.

4. The power amplifier arrangement according to claim 1, wherein the input impedance of the output impedance matching network is determined based on a desired load resistance of the first power amplifier, a coupling coefficient of the two coupled transmission lines and an output power backoff level.

5. The power amplifier arrangement according to claim 4, wherein the input impedance of the output impedance matching network is determined by an equation
$${R}_{L} = \frac{{k}^{2}}{{ξ}_{b}} \cdot {R}_{opt , m} ,$$
wherein R_{L} is the input impedance of the output impedance matching network, R_{opt,m} is the desired load resistance of the first power amplifier and k is the coupling coefficient of the two coupled transmission lines, ξ_{b} represents an output voltage level at which the second amplifier is at an onset, which is related to the output power backoff level by an equation P_{BO}=−20lo g (ξ_{b}), wherein P_{BO} is the output power backoff level.

6. The power amplifier arrangement according to claim 1, wherein a maximum current of the second power amplifier is determined based on a maximum current of the first power amplifier and an output power backoff level.

7. The power amplifier arrangement according to claim 6, wherein the maximum current of the second power amplifier is determined by an equation
$${I}_{a , max} = \frac{1 - {ξ}_{b}}{{ξ}_{b}} \cdot {I}_{m , max} ,$$
wherein I_{a,max} is the maximum current of the second power amplifier, I_{m,max} is the maximum current of the first power amplifier, ξ_{b} represents an output voltage level at which the second amplifier is at onset, which is related to the output power backoff level by an equation P_{BO}=−20lo g (ξ_{b}), wherein P_{BO} is the output power backoff level.

8. The power amplifier arrangement according to claim 1, wherein the input of the first power amplifier is coupled to the first output of the input power splitter via a first input impedance matching network.

9. The power amplifier arrangement according to claim 1, wherein the input of the second power amplifier is coupled to the second output of the input power splitter via a second input impedance matching network.

10. The power amplifier arrangement according to claim 1, wherein the output impedance matching network comprises multiple switchable impedance matching networks and the input impedance of the output impedance matching network is changed by selecting different impedance matching network.

11. The power amplifier arrangement according to claim 1, wherein the second power amplifier comprises multiple transistors with different sizes for changing the current of the second power amplifier.

12. The power amplifier arrangement according to claim 1, wherein the second power amplifier comprises a transistor, and wherein gate or base voltage of the second power amplifier is tuned for changing the current of the second power amplifier.

13. An electronic device comprising a power amplifier arrangement according to claim 1.

14. The electronic device according to claim 13 is any one of a transmitter, a transceiver, a base station, a mobile device, a user equipment, a wireless communication device for a communication system.
